(19) United States
(12) Patent Application Publication
(10) Pub. No.: US 2024/0069199 A1
(43) Pub. Date: Feb. 29, 2024

(54) RANGING DEVICE

(71) Applicant: SolidVue Inc., Seongnam-si Gyeonggi-do (KR)

(72) Inventor: Kitae KIM, Hanam-si Gyeonggi-do (KR)

(73) Assignee: SolidVue Inc., Seongnam-si Gyeonggi-do (KR)

(21) Appl. No.: 18/237,342

(22) Filed: Aug. 23, 2023

(30) Foreign Application Priority Data
Aug. 31, 2022 (KR) 10-2022-0109645

(51) Int. Cl. G01S 17/14; G01S 7/4863; G01S 7/487; G04F 10/00

(52) U.S. Cl. CPC G01S 17/14; G01S 7/4863; G01S 7/487; G04F 10/005

(57) ABSTRACT

A ranging device includes a sensor array including a plurality of sensors each sensing reflected light from object irradiated by a light source; a row driver configured to control the sensor array row by row to output a plurality of trigger signals; and a time detection circuit configured to detect time interval when reflected light arrives at the plurality of sensors since the object is irradiated by using the plurality of trigger signals, wherein the time detection circuit performs a first operation to detect a window period where a trigger signal is activated by using a trigger signal and a first clock signal, and performs a second operation to detect a section where the trigger signal is activated among a plurality of sections that divides the window period by using a second clock signal having smaller period than a period of the first clock signal.

### CROSS-REFERENCE TO RELATED APPLICATIONS

The present application claims priority under 35 U.S.C. § 119(a) to Korean Patent Application No. 10-2022-0109645, filed in the Korean Intellectual Property Office on Aug. 31, 2022, which is incorporated herein by reference in its entirety.

### BACKGROUND

### 1. Technical Field

Embodiments relate to a ranging device, and more particularly, to a ranging device using a rolling scan method.

### 2. Related Art

A Light Detection And Ranging (LiDAR) sensor is used as a ranging device.

A LiDAR sensor is a type of a ranging device that outputs 3D depth information by detecting distance and position of an object by irradiating infrared laser and analyzing reflected light.

LiDAR sensors have a very wide range of applications, including driving assistance devices and autonomous driving devices, as well as industrial and military applications.

A conventional mechanical LiDAR sensor physically rotate a sensor using a motor to scan the surroundings, so they are large, expensive, and have poor durability.

### SUMMARY

In accordance with an embodiment of the present disclosure, a ranging device may include a sensor array including a plurality of sensors each sensing reflected light from object irradiated by a light source; a row driver configured to control the sensor array row by row to output a plurality of trigger signals; and a time detection circuit configured to detect time interval when reflected light arrives at the plurality of sensors since the object is irradiated by using the plurality of trigger signals, wherein the time detection circuit performs a first operation to detect a window period where a trigger signal is activated by using a trigger signal and a first clock signal, and performs a second operation to detect a section where the trigger signal is activated among a plurality of sections that divides the window period by using a second clock signal having smaller period than a period of the first clock signal.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features, and explain various principles and beneficial aspects of those embodiments.

FIG. 1 illustrates an operation principle of a ranging device according to an embodiment of the present disclosure.

FIG. 2 illustrates a ranging device according to an embodiment of the present disclosure.

FIG. 3 illustrates a time-to-digital circuit circuit according to an embodiment of the present disclosure in detail.

FIG. 4 illustrates a first time-to-digital converter circuit and a histogram counter according to an embodiment of the present disclosure.

FIG. 5 is a timing diagram showing a first operation according to an embodiment of the present disclosure.

FIG. 6 illustrates a peak detection circuit according to an embodiment of the present disclosure.

FIG. 7 illustrates a filter according to an embodiment of the present disclosure.

FIG. 8 illustrates a second time-to-digital converter circuit according to an embodiment of the present disclosure.

FIG. 9 is a timing diagram showing a second operation according to an embodiment of the present disclosure.

FIG. 10 illustrates an operation of a decoder according to an embodiment of the present disclosure.

FIG. 11 illustrates a sensor according to an embodiment of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

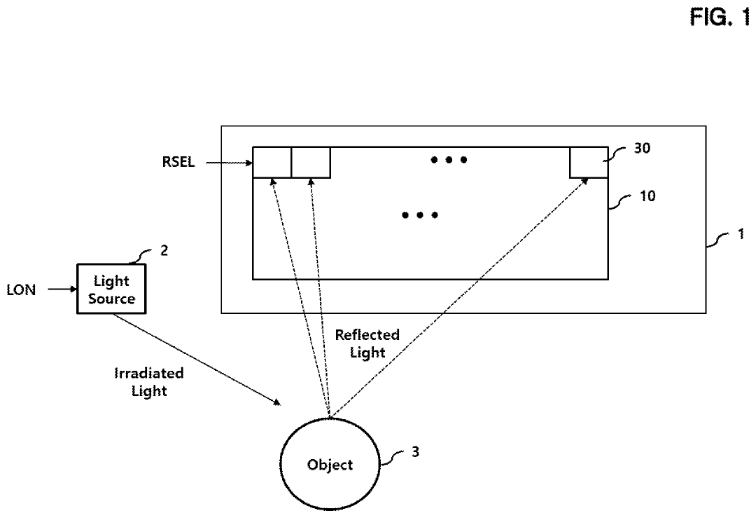

FIG. 1 illustrates an operation of a ranging device 1 according to an embodiment of the present disclosure.

The ranging device 1 detects reflected light reflected from an object 3 with a plurality of sensors 30 included in a row selected in a sensor array 10 according to a row selection signal RSEL after light is irradiated by a light source 2 according to a light activation signal RON.

Accordingly, in the present disclosure, the ranging device 1 detects reflected light row by row in the sensor array 10 and processes reflected light to measure distance between a sensor 30 and the object 3.

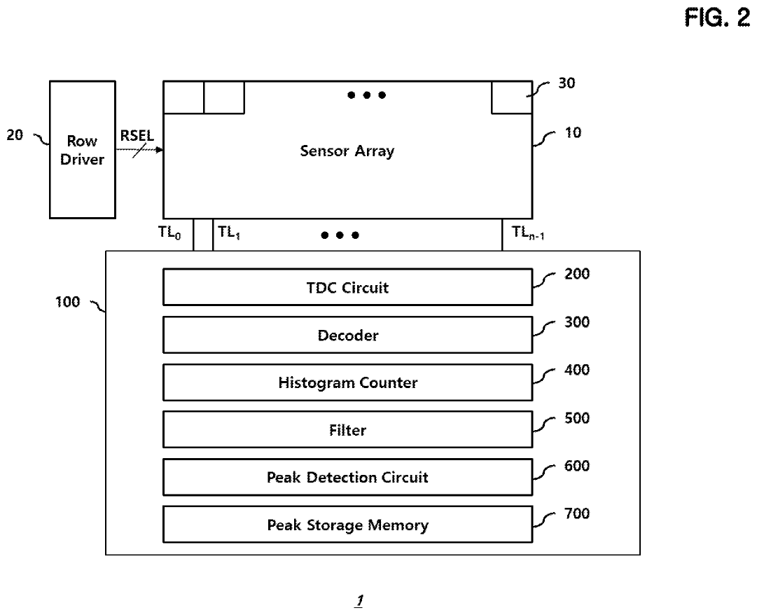

FIG. 2 is a block diagram showing the ranging device 1 according to an embodiment of the present disclosure.

The ranging device 1 includes the sensor array 10, a row driver 20, and a time detection circuit 100.

The sensor array 10 includes the plurality of sensors 30 arranged in rows and columns. Each sensor 30 outputs a trigger signal in response to received light after the object 3 is irradiated with laser beam output from the light source 2.

Hereinafter, a line from which a trigger signal is output is referred to as a trigger line TL.

The row driver 20 drives a plurality of sensors 30 included in a row of the sensor array 10, and a trigger signal output from each sensor 30 is output through a corresponding trigger line TL.

The row driver 20 may provide a row selection signal RSEL to the sensor array 10, and activation of sensors 30 in a row of the sensor array 10 is controlled according to a corresponding row selection signal RSEL.

The time detection circuit 100 processes trigger signals output from a plurality of sensors 30 included in one row of the sensor array 10 in parallel.

That is, the time detection circuit 100 performs signal processing in parallel on a plurality of trigger signals provided from a plurality of trigger lines TL₀, TL₁, . . . , TLₙ₋₁.

The time detection circuit 100 includes a time-to-digital converter (TDC) circuit 200, a decoder 300, a histogram counter 400, a filter 500, a peak detection circuit 600, and a peak storage memory 700.

Hereinafter, it is assumed that the TDC circuit 200, the decoder 300, the histogram counter 400, the filter 500, the peak detection circuit 600, and the peak storage memory 700 process a trigger signal corresponding to one trigger line.

In another embodiment, some of these elements may be included for each trigger line to perform an operation corresponding to a respective trigger line.

In another embodiment, one decoder 300 may be disposed for every two trigger lines. Other various modifications may be possible, but since these design changes through optimization by a person skilled in the art are obvious from this disclosure, detailed description of those will be omitted.

The TDC circuit 200 generates a data signal corresponding to a time from when laser beam is irradiated until a trigger signal is received and stores it in the histogram counter 300.

The TDC circuit 200 includes a first TDC circuit operating at a relatively lower resolution and a second TDC circuit operating at a relatively higher resolution.

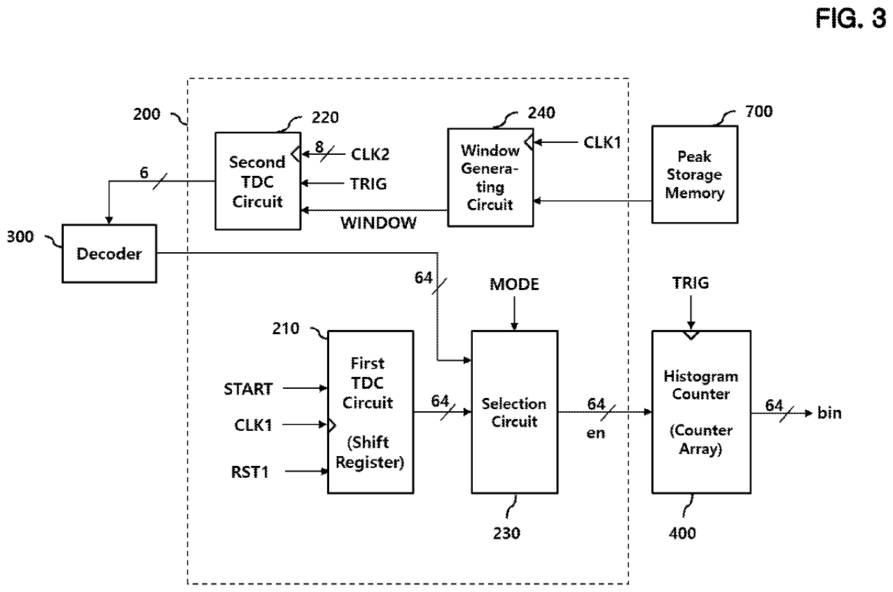

FIG. 3 is a block diagram showing the TDC circuit 200 in detail.

First, the histogram counter 400 is implemented as a counter array including a plurality of counters, and a counter activated by an activation signal en counts the trigger signal TRIG.

In this embodiment, the histogram counter 400 includes 64 counters, and each of the 64 counters corresponds to a time between irradiation of laser beam and reception of a trigger signal. This will be described in detail again below.

The TDC circuit 200 includes the first TDC circuit 210, the second TDC circuit 220, a selection circuit 230, and a window generating circuit 240.

Hereinafter, the operation of the first TDC circuit 210 is referred to as a first operation, and the operation of the second TDC circuit 220 is referred to as a second operation.

The first operation and the second operation may be separately represented by the mode signal MODE.

In addition, a histogram stored in the histogram counter 400 according to the first operation may be referred to as a first histogram, and a histogram stored in the histogram counter 400 according to the second operation may be referred to as a second histogram.

The first TDC circuit 210 generates information corresponding to time interval from activation of the start signal START to activation of the trigger signal TRIG using the first clock signal CLK1.

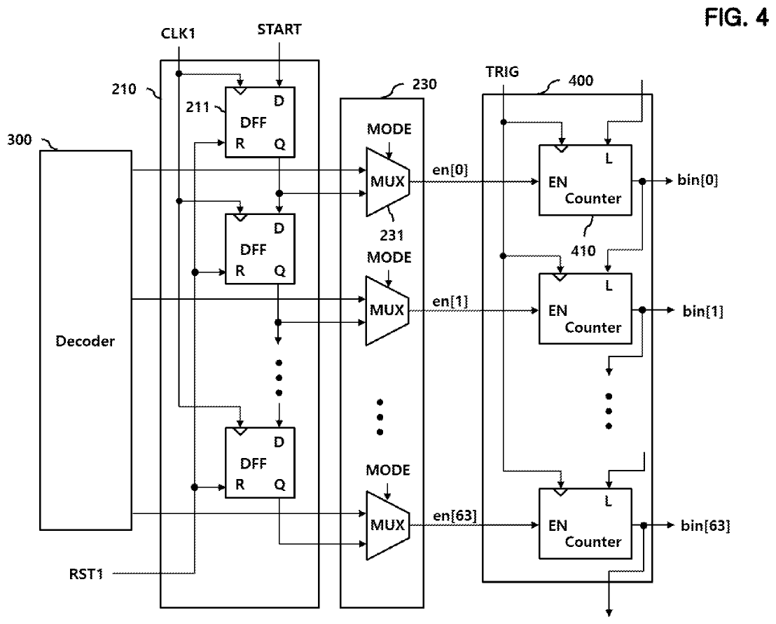

As shown in FIG. 4, the first TDC circuit 210 is implemented with a shift register that shifts the start signal START according to the first clock signal CLK1.

The selection circuit 230 selects outputs of the first TDC circuit 210 in the first operation, and in response to this, a counter in the histogram counter 400 is activated according to the activation signal en and an activated counter 410 performs a count operation according to the trigger signal TRIG.

As shown in FIG. 4, the selection circuit 230 includes 64 multiplexers 231 each of which selects an output of a corresponding flip-flip 211 or a corresponding bit among 64 bits output from the decoder 300 according to the mode signal MODE to generate an activation signal en, which is a 64-bit signal.

The selection circuit 230 selects the output of the first TDC circuit 210 in the first operation and selects the output of the decoder 300 generated according to the output of the second TDC circuit 220 in a second operation.

In this embodiment, the shift register includes 64 flip-flops 211 connected in a row and can be reset according to the first reset signal RST1.

The first operation is performed multiple times, and while the first operation is being performed, the histogram counter 400 accumulates count results to generate a first histogram.

The window generating circuit 240 generates a window signal WINDOW activated according to a peak detected during a peak detection operation for the first histogram.

Hereinafter, a period in which the window signal WINDOW is activated may be referred to as a peak period or a window period.

The peak detection operation and the method of generating the window signal WINDOW will be described in detail below.

The second TDC circuit 220 generates information indicating time interval until the trigger signal TRIG is activated after the window signal WINDOW is activated by using the second clock signal CLK2 having a higher frequency than the first clock signal CLK1.

Hereinafter, a period of the first clock signal CLK1 may be referred to as a first period P1, and a period of the second clock signal CLK2 may be referred to as a second period P2. In this embodiment, the first period P1 is four times the second period P2, but is not necessarily limited thereto.

The decoder 300 decodes the output of the second TDC circuit 230 and outputs 64 signals.

The selection circuit 230 selects the output of the decoder 300 in the second operation, and accordingly, some counters in the histogram counter 400 are activated to perform a count operation according to the trigger signal TRIG.

Similar to the first operation, the second operation is performed multiple times, and while the second operation is being performed, the histogram counter 400 accumulates count results to generate a second histogram.

The peak detection circuit 600 generates peak information for each of the first histogram and the second histogram.

By combining the peak information generated by the first and second operations, the time interval from time when the laser beam is irradiated until time when the reflected light is received by the sensor can be more accurately measured and the distance to the object from the sensor 30 can be determined.

The histogram counter 400 is a counter array including a plurality of counters and counts trigger signals from one counter activated according to an activation signal en.

As shown in FIG. 4, the histogram counter 400 includes 64 counters 410.

A counter 410 included in the histogram counter 400 may be referred to as a first counter 410.

Each counter 410 is activated according to an output of the corresponding multiplexer 231 and counts the trigger signal TRIG.

Each of the plurality of counters 410 may operate in the form of a shift register by loading the previous counter value. Since the technique of using a plurality of counters in the form of a shift register is well known, detailed disclosure thereof will be omitted.

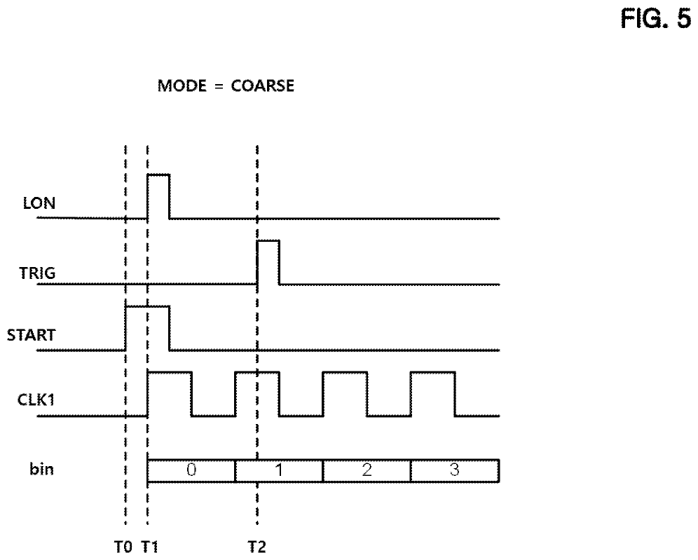

FIG. 5 is a timing diagram illustrating a first operation, where the mode signal MODE is represented as COARSE.

When the start signal START is activated at TO, a pulse of the light activation signal LON is generated at T1 in synchronization with the first clock signal CLK1, and thus light such as laser beam is irradiated.

When the reflected light reaches the sensor 30 at T2 after a certain time has elapsed from T1, a pulse of the trigger signal TRIG is generated. At this time, the certain time varies according to the distance between the sensor 30 and the object 3.

In the first operation, the time between T1 and T2 is measured using the first clock signal CLK1, which corresponds to a relatively lower resolution value compared to the second operation.

In FIG. 5, since T2 when the trigger signal TRIG belongs to a second first period P1 after T1, the value bin[1] of a second counter in the histogram counter 400 activated by the activation signal en[1] is increased by 1.

As aforementioned, the first operation is repeated multiple times, for example, 80 times, and each time the histogram counter 400 performs the first operation, a counter value of one of the plurality of counters increases, and as a result, the first histogram is created.

It is common for one trigger signal to be generated by one laser irradiation, but in practice, a trigger signal may be additionally generated by noise. That is, two or more trigger signals, including a trigger signal by reflected laser and a trigger signal by noise, may be generated at different times, and in this case, values may be increased in two or more counters whenever the first operation is performed.

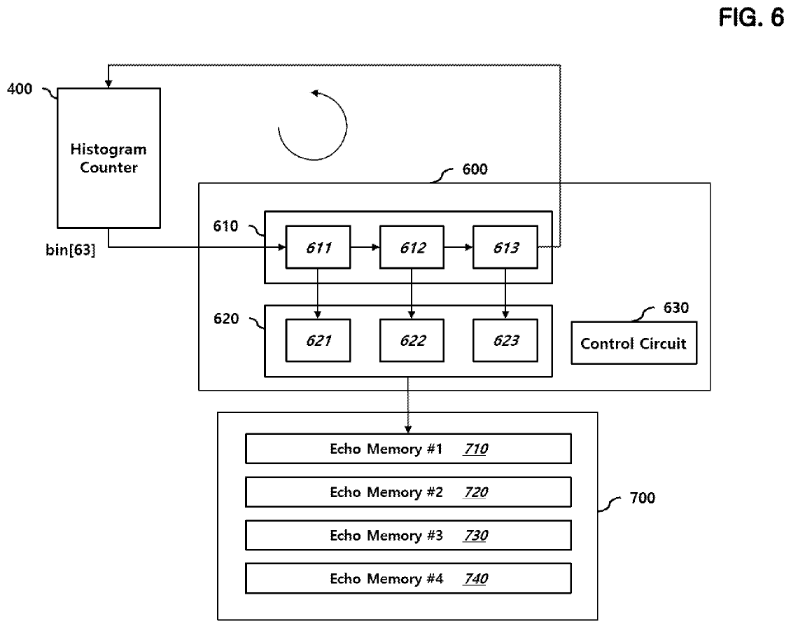

FIG. 6 illustrates the peak detection circuit 600 and a peak detection operation thereof according to an embodiment of the present disclosure.

The peak detection circuit 600 includes a first register array 610, a second register array 620, and a control circuit 630.

In this embodiment, the first register array 610 includes three first registers 611, 612, and 613, and the second register array 620 includes three second registers 621, 622, and 623.

The first register array 610 may be connected together with the histogram counter 400 in the form of a ring and function like a shift register.

Values of the first registers 611, 612, and 613 and the second registers 621, 622, and 623 are initialized to zero.

In the present embodiment, during the peak detection operation, the plurality of counters 410 included in the histogram counter 400 and the first register array 610 are connected in a ring shape to perform a shift operation in a counterclockwise direction.

Accordingly, the values bin[63], bin[62], and bin[61] of the histogram counter 400 are sequentially shifted to the first register array 610.

The control circuit 630 compares the value of the first register 612 and the value of the second register 622.

When the value of the first register 612 is greater than the value of the second register 622, the values of the first register array 610 are stored in the second register array 620.

At this time, the control circuit 630 manages the counter address corresponding to values stored in the second register array 620.

In FIG. 4, the address of the counter outputting bin[0] can be indicated as #0, and the address of the counter outputting bin[63] can be indicated as #63.

In FIG. 6, after the 67th shift, the plurality of counters 410 included in the histogram counter 400 have original values, and this is referred to as one peak detection operation.

When one peak detection operation is completed, the second register 622 stores the peak value, and the second registers 621 and 623 store values around the peak.

When one peak detection operation is completed, the control circuit 630 stores the counter address corresponding to the value of the second register array 620 in the echo memory 710.

In this embodiment, counter addresses corresponding to two largest values among the values stored in the second register array 620 are first stored.

For example, when the peak address is #13, addresses #12 and #14 are stored in the echo memory 710 together.

At this time, if the counter value corresponding to counter address #12 is greater than the counter value corresponding to counter address #14, the counter addresses are stored in the order of #12, #13, and #14, and if the counter value corresponding to counter address #14 is greater than the counter value corresponding to counter address #12, the counter addresses can be stored in the order of #13, #14, and #12.

In this embodiment, the window signal WINDOW is generated using first two addresses stored in the echo memory 710, which will be described in detail below.

When one peak detection operation is completed, the histogram counter 400 resets the counter 410 corresponding to the counter address stored in the echo memory 710.

A plurality of peaks may be detected by repeating the above-described peak detection operation multiple times, and addresses corresponding to the detected peaks may be sequentially stored in the echo memories 720 to 740 as described above.

Through this, the peak storage memory 700 stores a plurality of peak information detected by the histogram counter 400.

During the second operation, the window generating circuit 240 refers to the peak storage memory 700 and generates the window signal WINDOW according to the first clock signal CLK1.

In the embodiment disclosed in FIG. 6, the output of the histogram counter 400 is directly input to the peak detection circuit 600.

In another embodiment, the output of the histogram counter 400 is provided to the filter 500, and the output of the filter 500 is provided to the peak detection circuit 600.

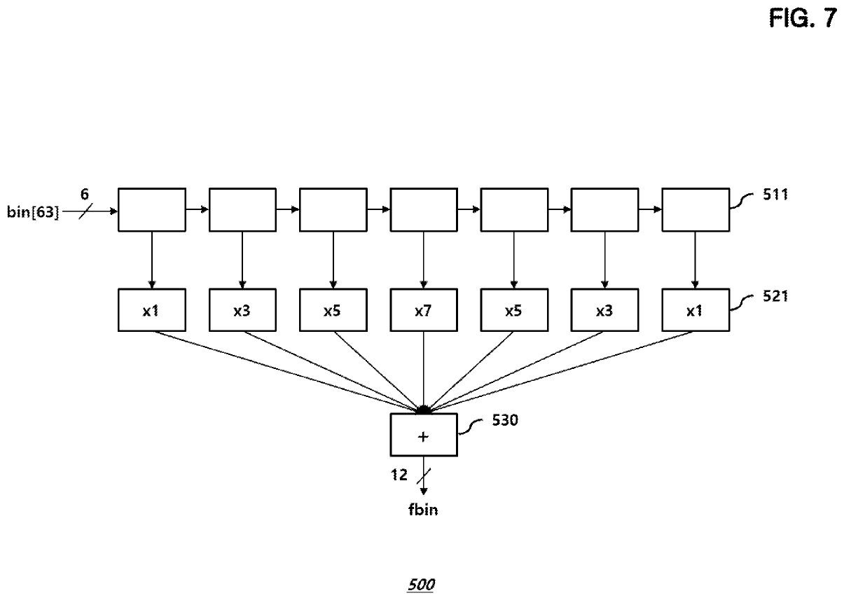

FIG. 7 is a block diagram showing a filter 500 according to an embodiment of the present disclosure.

In this embodiment, the filter 500 includes a plurality of filter registers 511, a plurality of multiplication circuits 521 for multiplying the outputs of the plurality of filter registers 511 with a plurality of coefficients, respectively, and an adder circuit 530 for adding the outputs of the plurality of multiplication circuits 521.

Since the filter 500 shown in FIG. 7 is well known as a convolution filter, a detailed description thereof will be omitted.

When the output fbin of the filter 500 is used in the peak detection circuit 600, 7 shift operations must be added for one peak detection operation.

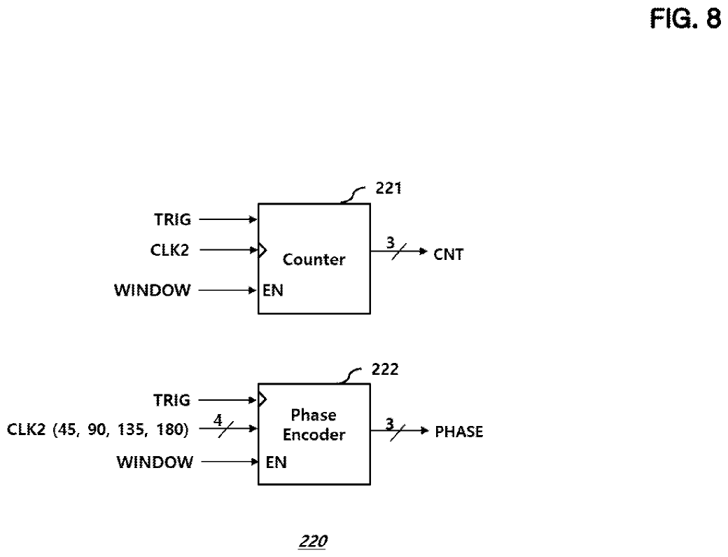

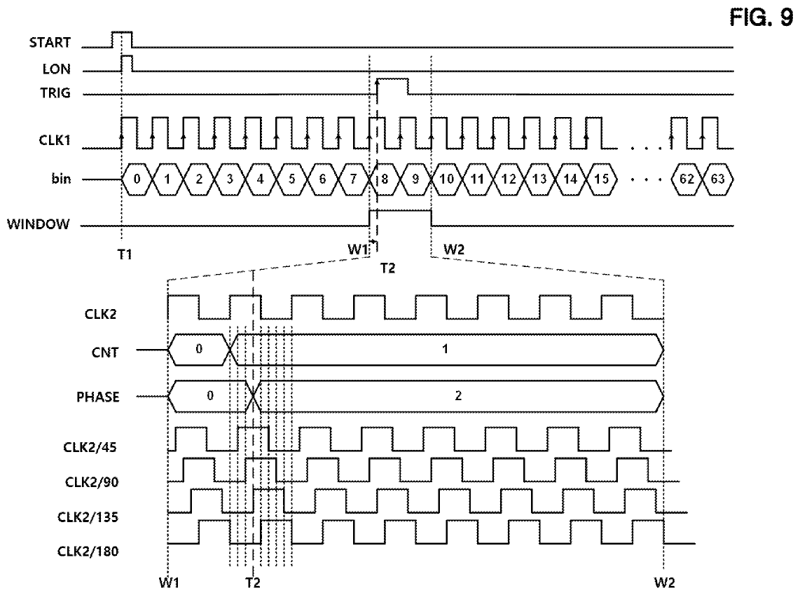

Hereinafter, the second operation will be described in detail with reference to FIGS. 8 and 9.

First, in the second operation, a period in which the window signal WINDOW is activated, that is, a window period or a peak period is divided into a plurality of sections, and the number of occurrences of the trigger signal TRIG is counted in each section.

Through this, the time point at which the trigger signal TRIG is enable is measured with higher resolution.

In this embodiment, two first periods P1 corresponding to one window period are divided into 64 sections and each section is related to one of 64 counters included in the histogram counter 400.

Accordingly, in the second operation, one of the 64 counters 410 included in the histogram counter 400 counts the trigger signal TRIG.

The second TDC circuit 220 generates a multi-bit digital signal by referring to the window signal WINDOW and the trigger signal TRIG, and the decoder 300 decodes the multi-bit digital signal output from the second TDC circuit 220. Thus, one of 64 counters 410 included in the histogram counter 400 is activated.

FIG. 8 is a block diagram showing a specific configuration of the second TDC circuit 220.

The second TDC circuit 220 includes a counter 221 and a phase encoder 222.

Hereinafter, the counter 221 included in the second TDC circuit 220 may be referred to as a second counter 221.

The counter 221 is activated according to the window signal WINDOW, counts the second clock signal CLK2, and stops counting operation according to the trigger signal TRIG.

In this embodiment, since the window signal WINDOW is activated for twice the first period P1 and the first period P1 is four times the second period P2, the output of the counter 221 ranges from 0 to 7, which can be expressed with 3 bits.

The phase encoder 222 is activated according to the window signal WINDOW and encodes the phase by latching the value of multi-phase second clock signals according to the trigger signal TRIG.

The multi-phase second clock signals are clock signals CLK2/45, CLK2/90, CLK2/135, and CLK2/180 delayed by 45 degrees, 90 degrees, 135 degrees, and 180 degrees, respectively based on the phase of the second clock signal CLK2 applied to the counter 221.

Accordingly, the phase encoder 222 divides one period of the second clock signal CLK2 into 8 sections.

Table 1 shows values of the latched multi-phase second clock signals and corresponding phase values.

TABLE 1

| CLK2/45 | CLK2/90 | CLK2/135 | CLK2/180 | PHASE (3bits) |
|---|---|---|---|---|
| 0 | 0 | 0 | 0 | 0 |
| 1 | 0 | 0 | 0 | 1 |
| 1 | 1 | 0 | 0 | 2 |
| 1 | 1 | 1 | 0 | 3 |
| 1 | 1 | 1 | 1 | 4 |
| 0 | 1 | 1 | 1 | 5 |
| 0 | 0 | 1 | 1 | 6 |
| 0 | 0 | 0 | 1 | 7 |

In this embodiment, each of the count signal CNT and the phase signal PHASE is a 3-bit signal, and the decoder 300 decodes a total of 6-bit signal to generate 64 1-bit signals.

Accordingly, when the trigger signal TRIG is input, a counter 410 corresponding to a counter address #(8×CNT+PHASE) in the histogram counter 400 is activated.

FIG. 9 is a timing diagram showing an operation of the second TDC circuit 220.

As described above, the window signal WINDOW is a signal generated according to a peak detected as a result of the first operation. As described above, in this embodiment, the window signal WINDOW can be generated by referring to the first two addresses of the echo memory.

In FIG. 9, it is assumed that the window period corresponds to #8 and #9 of the counter address.

Accordingly, in the second operation, the window signal generating circuit 240 generates the window signal WINDOW activated between the time W1 when 8×P1 has elapsed since T1 and the time W2 when 10×P1 has elapsed.

The counter 221 starts counting at W1 according to the second clock signal CLK2 until the trigger signal TRIG is activated at T2.

In this embodiment, it is assumed that the count value starts with 0 when the window signal WINDOW is activated, and accordingly, the output CNT of the counter 221 becomes 1 at T2.

The phase encoder 222 is activated according to the window signal WINDOW and latches the values of the four multi-phase clock signals at T2.

In FIG. 9, the latched values are 1, 1, 0, 0 in phase order, and the corresponding phase value is 2 as shown in Table 1.

Accordingly, the 10th counter among the counters included in the histogram counter 400 corresponding to the CNT and the PHASE, which are 1 and 2, respectively, counts the trigger signal TRIG and value of bin[10] is increased by 1.

When the second operation is performed multiple times, the second histogram generated by the trigger signal TRIG is stored in the histogram counter 400.

The peak detection circuit 600 may detect a peak using the second histogram in the same manner as described above.

However, unlike the peak detection operation using the first histogram, in the peak detection operation using the second histogram, there is no need to generate a window period, so it is sufficient to find one peak.

Accordingly, in FIG. 6, it is sufficient to perform the peak detection operation using only one of the first register 611 and the second register 621.

Of course, the control circuit 630 may compare values of the first register 611 and the second register 621.

The remaining two first registers 612 and 613 may be used to accumulate values of the plurality of counters 410 included in the histogram counter 400.

The accumulated value is a value corresponding to the intensity of the reflected light measured by the sensor 30, and data such as an image may be generated from the intensity of the reflected light measured for the entire sensor array 10.

That is, in this embodiment, the control circuit 630 can simultaneously control the intensity measurement while controlling the peak detection operation for the second histogram.

The intensity value corresponding to the sensor 30 may be stored in a predetermined address of the peak storage memory 700.

By combining the peak address detected in the second histogram with the section where the window signal WINDOW is activated, the peak occurrence time can be measured more precisely, and the distance from the sensor 30 to the object can be more precisely measured.

For example, it is assumed that the address of the peak detected after the second operation in FIG. 9 is #10. In this case, the elapsed time required for the light reflected from the object to reach the sensor 30 after laser irradiation can be calculated as Equation 1.

(Elapsed Time)=8×P1+(2×P1)/64×10 [Equation 1]

The above operation assumes that the second operation is performed in one peak period stored in the peak storage memory 700.

For the remaining peak periods stored in the peak storage memory 700, the second operation may be repeated in the same manner to precisely determine each peak position.

The second operation may be simultaneously performed on a plurality of peaks stored in the peak storage memory 700.

In this case, in order not to lower the precision of the peak position during the second operation, the number of histogram counters 400 may be increased corresponding to the number of window periods.

In this case, since a plurality of histogram counters 400 are included, the area of the circuit may increase.

Accordingly, the second operation for a plurality of peaks can be simultaneously performed using one histogram counter 400.

To this end, 64 counters 410 included in the histogram counter 400 may be divided into a plurality of groups according to the number of windows.

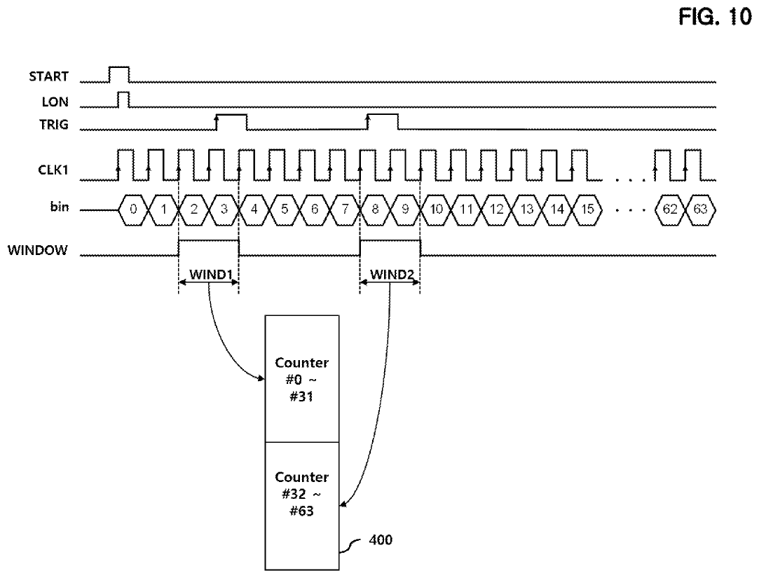

FIG. 10 shows a case in which the second operation is simultaneously performed for two window periods.

When the second operation is simultaneously performed for two window periods stored in two echo memories, 32 counters are allocated for each window period, and the precision during the second operation is halved.

In FIG. 10, counters 410 from 0 to 31 of the histogram counter 400 are allocated to the first window period WIND1 corresponding to a smaller address, and counters 410 from 32 to 63 of the histogram counter 400 are allocated to the second window period WIND2 corresponding to a larger address.

To this end, the decoder 300 may additionally refer to the peak storage memory 700 in addition to the output of the second TDC circuit 220.

In the case of simultaneously performing the second operation for a larger number of window periods, a method of allocating a counter corresponding to each window can be easily understood by those skilled in the art from the above disclosure, and thus an additional example is omitted.

When a plurality of peaks are detected, some peaks of lower importance may be ignored to reduce peak detection time and consequently prevent loss of precision of the peak position.

For example, when a plurality of peaks are detected, the size of each peak is compared with a threshold value, and peaks below the threshold value may be disregarded. Accordingly, the number of window periods is also reduced.

As another example, when a plurality of peaks are detected during a peak detection operation using a first histogram, peaks corresponding to longer distances may be regarded as having low importance.

For example, if the threshold distance is 100 m and the corresponding counter address is #50, peaks located after #51 can be ignored.

Depending on embodiments, it is possible to select peaks of higher importance by applying various criteria, but since the design change is obvious to a person skilled in the art, additional examples are omitted.

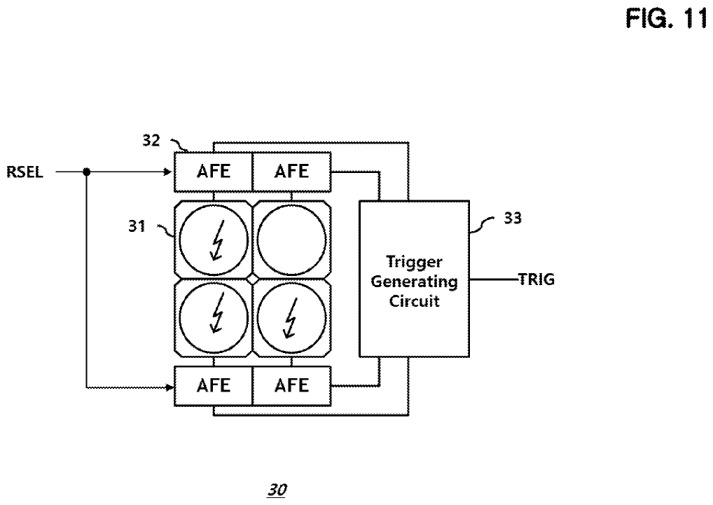

FIG. 11 shows structure of a sensor 30 according to an embodiment of the present disclosure.

One sensor 30 may include a plurality of light receiving elements 31 such as single-photon avalanche diodes (SPADs).

The sensor 30 includes a plurality of analog front-end (AFE) circuits 32 that convert outputs of the light receiving elements 31 into electrical signals respectively, and a trigger signal generating circuit 33 that generates a trigger signal TRIG according to outputs of the plurality of AFE circuits 32.

In this embodiment, an AFE circuit 32 is activated by the row selection signal RSEL and generates a pulse signal having a constant pulse width when a corresponding light receiving element 31 receives an optical signal, that is reflected light.

The trigger signal generating circuit 33 may generate a trigger signal TRIG by performing an OR operation on signals provided from the plurality of AFE circuits 32.

In FIG. 11, there are four light receiving elements 31 included in one sensor 30, but the number of light receiving elements 31 included in the sensor 30 may be variously set according to embodiments.

Although various embodiments have been described for illustrative purposes, it will be apparent to those skilled in the art that various changes and modifications may be made to the described embodiments without departing from the spirit and scope of the disclosure as defined by the following claims.

What is claimed is:

1. A ranging device comprising:
a sensor array including a plurality of sensors each sensing reflected light from object irradiated by a light source;
a row driver configured to control the sensor array row by row to output a plurality of trigger signals; and
a time detection circuit configured to detect time interval when reflected light arrives at the plurality of sensors after the object is irradiated by using the plurality of trigger signals,
wherein the time detection circuit performs a first operation to detect a window period where a trigger signal is activated by using a trigger signal and a first clock signal, and performs a second operation to detect a section where the trigger signal is activated among a plurality of sections that divides the window period by using a second clock signal having smaller period than a period of the first clock signal.

2. The ranging device of claim 1, wherein the time detection circuit comprises:
a histogram counter including a plurality of first counters where one of the plurality of first counters is activated according to a plurality of activation signals and an activated first counter counts the trigger signal;
a time-to-digital converter (TDC) circuit configured to generate time difference information according to the second operation and a plurality of shift signals generated according to the first operation, and to generate the plurality of activation signals according to a plurality of decoding signals;
a decoder configured to generate the plurality of decoding signals by decoding the time difference information; and
a peak detection circuit configured to perform a first peak detection operation to detect a peak in a first histogram stored in the histogram counter during the first operation, and to perform a second peak detection operation to detect a peak in a second histogram stored in the histogram counter during the second operation; and
a peak storage memory storing information on location of a detected peak.

3. The ranging device of claim 2, wherein the TDC circuit includes:
a first TDC circuit configured to generate a plurality of shift signals sequentially activated after a start signal according to the first clock signal;
a window generating circuit configured to generate a window signal identifying a window period corresponding to a peak detected during the first operation according to the first clock signal;
a second TDC circuit configured to generate the time difference information corresponding to time between beginning of the window period and the trigger signal according to the second clock signal; and
a selection circuit configured to provide the plurality of shift signals as the plurality of activation signals during the first operation and to provide the plurality of decoding signals as the plurality of activation signals during the second operation.

4. The ranging device of claim 3, wherein the second TDC circuit includes:
a second counter configured to count the second clock signal while the window signal is activated; and
a phase encoder configured to generate a phase signal by sampling a plurality of multi-phase second clock signals having different phases from the second clock signal according to the trigger signal after the window signal is activated,
wherein the decoder generates the plurality of decoding signals by decoding an output of the second counter and an output of the phase encoder.

5. The ranging device of claim 2, wherein the peak detection circuit includes:
a predetermined number of first registers;
a predetermined number of second registers; and
a control circuit configured to compare a value of one of the predetermined number of first registers and a value of one of the predetermined number of second registers and to store values of the predetermined number of first registers into the predetermined number of second registers.

6. The ranging device of claim 5, wherein when all of counter values of the histogram counter are compared during the first operation, the control circuit stores a predetermined counter address corresponding to values of the predetermined number of second registers in the peak storage memory.

7. The ranging device of claim 6, wherein the control circuit separately stores a selected number of counter addresses among the predetermined number of counter addresses in the peak storage memory, and the window generating circuit generates the window signal referring to the selected number of counter addresses.

8. The ranging device of claim 5, wherein a plurality of counters in the histogram counter and the predetermined number of first registers are connected to form a ring, and the peak detection circuit performs the peak detection operation by shifting the values in the ring until values of the histogram counter are recovered to original values.

9. The ranging device of claim 8, wherein the time detection circuit further includes a filter configured to filter a value output from the histogram counter to output a filtered value, and
wherein the histogram counter, the filter, and the predetermined number of first registers are connected to form the ring, and the peak detection circuit performs the peak detection operation by shifting the values in the ring until values of the histogram counter are recovered to original values.

10. The ranging device of claim 9, wherein the filter includes:
a plurality of filter registers configured to sequentially shift and store an output of the histogram counter;
a plurality of multiplication circuits configured to multiply outputs of the plurality of filter registers with a plurality of coefficients respectively; and
and adder circuit configured to add outputs of the plurality of multiplication circuits.

11. The ranging device of claim 5, wherein the peak detection circuit performs the first peak detection operation multiple times, and the peak detection circuit resets counter values corresponding to the predetermined number of first counters of the histogram counter when the first peak detection operation is terminated.

12. The ranging device of claim 11, wherein when a plurality of window periods are detected during the first operation, the decoder divides a plurality of first counters in the histogram counter into a plurality of groups corresponding to a number of detected window periods, and generates the decoding signal so that one window corresponds to one group.

13. The ranging device of claim 5, wherein when a value of a peak detected in the first peak detection operation is smaller than a threshold value, the peak detection circuit ignores result of the first peak detection operation.

14. The ranging device of claim 5, wherein when a value of a peak detected in the first peak detection operation corresponds to a distance longer than a threshold distance, the peak detection circuit ignores result of the first peak detection operation.

15. The ranging device of claim 5, wherein the control circuit compares a value of a selected first register of the predetermined number of first registers with a value of a corresponding second register and stores values of the predetermined number of first registers in the predetermined number of second registers during the second peak detection operation, and
wherein the control circuit accumulates values of the histogram counter in one or more first registers among the predetermined number registers except the selected first register.

16. The ranging device of claim 1, wherein the sensor includes:
a plurality of light receiving elements configured to generate output signals after receiving the reflected light respectively;
a plurality of analog front end circuit configured to generate pulse signals according to the output signals of the plurality of light receiving elements respectively; and
a trigger signal generating circuit configured to generate a trigger signal according to the plurality of pulse signals.
